(19) United States
(12) Patent Application Publication
(10) Pub. No.: US 2020/0185877 A1
(43) Pub. Date: Jun. 11, 2020

(54) OPTICAL MODULE

(71) Applicant: SHARP KABUSHIKI KAISHA, Sakai City, Osaka (JP)

(72) Inventors: YOSHINOBU KAWAGUCHI, Sakai City (JP); SHINJI OSAKI, Sakai City, Osaka (JP); TAKATOSHI MORITA, Sakai City (JP); SHOGO YANASE, Sakai City, Osaka (JP); TOSHIO KAGAWA, Sakai City (JP); TERUYUKI OOMATSU, Sakai City (JP); KAZUAKI KANEKO, Sakai City (JP); SHIGETOSHI ITO, Sakai City (JP)

(21) Appl. No.: 16/313,145

(22) PCT Filed: Jan. 31, 2017
(86) PCT No.: PCT/JP2017/003451

§ 371 Date: Dec. 25, 2018

(30) Foreign Application Priority Data
Jun. 29, 2016 (JP) 2016-129219

(51) Int. Cl. H01S 5/022; H01S 5/40

(52) U.S. Cl. CPC H01S 5/0224; H01S 5/32341; H01S 5/4056; H01S 5/4025

(57) ABSTRACT

In an optical module (first module (1)), a plurality of semiconductor laser elements (a first semiconductor laser element (21) through a third semiconductor laser element (23)) that output light of wavelengths which are different from each other from light emitting points are mounted on a base member (10). The base member (10) has a reference surface (11) serving as a reference in a height direction (Z) and a mounting surface (a first mounting surface (12a) and a second mounting surface (12b)) on which the semiconductor laser elements are mounted. At least some of the plurality of semiconductor laser elements are different from each other in a height (a first light emission height (TL1) through a third light emission height (TL3)) from a surface in contact with the mounting surface to the light emitting points, and are substantially equal in a height (reference height (HL)) from the reference surface to the light emitting points.

### TECHNICAL FIELD

The present invention relates to an optical module in which a plurality of semiconductor laser elements that respectively output light of wavelengths different from each other from light emitting points are mounted on a base member.

### BACKGROUND ART

As an optical module of an image display apparatus such as a projector or a head-mounted display, an optical module including a light source that emits light of wavelengths of blue, green, and red, multiplexing light of a plurality of wavelengths, and radiating the multiplexed light has been proposed. In recent years, such optical module has been mounted also on a wearable device or a mobile device and further reduction in size of the optical module has been desired. Specifically, a very small projector is proposed in which the optical module and an MEMS mirror are combined (for example, refer to PTL 1). Upon the reduction in size, characteristics may greatly change if each member is displaced, and therefore it is required to accurately mount each member to a package.

### CITATION LIST

### Patent Literature

PTL 1: Japanese Unexamined Patent Application Publication No. 2016-15415

### SUMMARY OF INVENTION

### Technical Problem

A three-color light source described in PTL 1 includes three laser diodes that emit laser light of different wavelengths, and outputs light by multiplexing three laser light beams by a carrier mounted on a temperature control element, collimate lenses, and wavelength filters. In the three-color light source, the laser diodes are mounted on the carrier through sub-mounts, and by adjusting heights (thicknesses) of the sub-mounts, laser light output points have equal heights.

Meanwhile, workability, heat dissipation, or the like of a laser diode changes in accordance with a thickness of a sub-mount, and therefore it is desirable that the sub-mount has an optimum thickness according to a wavelength. In consideration of this, in a three-color light source of the related art, when the thickness of a sub-mount changes, a laser light output point is shifted, and thus it is difficult to set the thickness of the sub-mount as desired, which may cause workability or the like to be deteriorated.

The invention is made to solve the aforementioned problem and an object thereof is to provide an optical module that is able to facilitate attachment and adjustment of an optical component or the like to a plurality of semiconductor laser elements.

### Solution to Problem

An optical module according to the invention is an optical module in which a plurality of semiconductor laser elements that output light of wavelengths different from each other from light emitting points are mounted on a base member, in which the base member has a reference surface serving as a reference in a height direction and a mounting surface on which the semiconductor laser elements are mounted, the mounting surface includes a plurality of mounting portions having different positions in the height direction, at least some of the plurality of semiconductor laser elements having distances different from each other in the height direction from a surface in contact with the mounting surface to the light emitting points, and the plurality of semiconductor laser elements have distances substantially equal to each other in the height direction from the reference surface to the light emitting points.

The optical module according to the invention may be configured such that the plurality of semiconductor laser elements include chips that output light, and at least one of the plurality of chips is subjected to junction-down mounting and at least one of the other chips is subjected to junction-up mounting.

The optical module according to the invention may be configured such that the plurality of semiconductor laser elements include chips that output light, and the plurality of chips are subjected to junction-down mounting.

The optical module according to the invention may be configured such that the plurality of semiconductor laser elements include chips that output light, and the plurality of chips are subjected to junction-up mounting.

The optical module according to the invention may be configured such that in a case where a surface from which light is output is a light output surface and a direction in which light is output is an output direction in the plurality of semiconductor laser elements, at least two of the plurality of semiconductor laser elements have positions of the light output surface different from each other in the output direction.

The optical module according to the invention may be configured such that the mounting surface is provided with a recess formed to be lower than a surrounding area.

The optical module according to the invention may be configured such that at least two of the plurality of semiconductor laser elements have directions different from each other in which light is output.

### Advantageous Effects of Invention

According to the invention, provided is an optical module in which mounting portions that have heights different from each other are provided in a base member and heights of a plurality of semiconductor laser elements to light emitting points are made uniform, and therefore an influence on an optical component or the like is eliminated and attachment and adjustment of the optical component are able to be facilitated.

### BRIEF DESCRIPTION OF DRAWINGS

FIG. 1A is a schematic top view of an optical module according to a first embodiment of the invention.

FIG. 1B is a schematic side view of the optical module illustrated in FIG. 1A.

FIG. 2 is a schematic top view illustrating the optical module to which a frame is attached.

FIG. 3A is a schematic top view of an optical module according to a second embodiment of the invention.

FIG. 3B is a schematic side view of the optical module illustrated in FIG. 3A.

FIG. 4A is a schematic top view of an optical module according to a third embodiment of the invention.

FIG. 4B is a schematic side view of the optical module illustrated in FIG. 4A.

FIG. 5A is a schematic top view of an optical module according to a fourth embodiment of the invention.

FIG. 5B is a schematic side view of the optical module illustrated in FIG. 5A.

### DESCRIPTION OF EMBODIMENTS

### First Embodiment

An optical module according to a first embodiment of the invention will be described below with reference to drawings. Note that, in the drawings, in consideration of visibility, a height difference is exaggerated, for example, by changing an aspect ratio, and dimensions are different from actual dimensions.

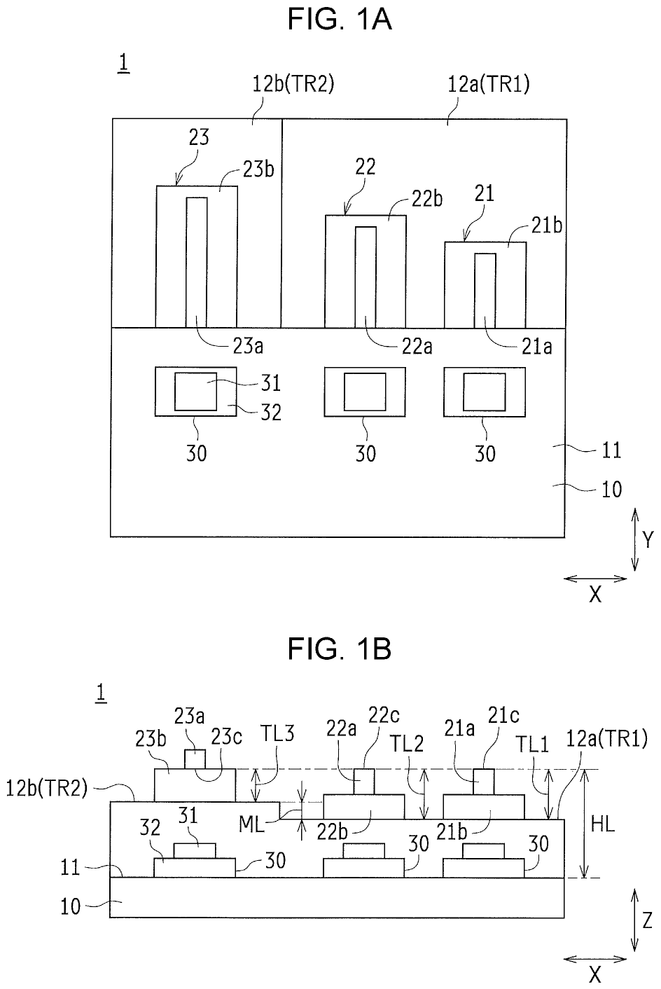

FIG. 1A is a schematic top view of the optical module according to the first embodiment of the invention and FIG. 1B is a schematic side view of the optical module illustrated in FIG. 1A.

In the optical module (first module 1) according to the first embodiment of the invention, a plurality of semiconductor laser elements that output light of wavelengths different from each other from light emitting points are mounted on a base member 10. In the present embodiment, three semiconductor laser elements of a first semiconductor laser element 21, a second semiconductor laser element 22, and a third semiconductor laser element 23 are mounted on the base member 10.

The base member 10 is a substrate that is rectangular in top view and has a reference surface 11 serving as a reference in a height direction Z and a mounting surface (a first mounting surface 12a and a second mounting surface 12b) on which the semiconductor laser elements are mounted. In the present embodiment, the base member 10 has a dimension of 10 mm in a lateral direction X and 10 mm in a longitudinal direction Y. The base member 10 is formed of metal, such as aluminum, copper, or iron, or an alloy thereof and preferably has a gold-plated surface.

The reference surface 11 (a lower part of the base member 10 in FIG. 1A) is a uniformly flat surface on which an optical component, for example, such as a lens, a waveguide element, a prism, a wavelength selection filter, or a photodiode is mounted. In the present embodiment, three photodiodes 30 corresponding to the three semiconductor laser elements are arranged on the reference surface 11. Each of the photodiodes 30 is constituted by a PD chip 31 that detects an output of a corresponding one of the semiconductor laser elements and a PD holding unit 32 that holds the PD chip 31. Only the photodiodes 30 are mounted in the present embodiment, but there is no limitation thereto and different types of optical components may be mounted as needed.

The mounting surface (an upper part of the base member 10 in FIG. 1A) is provided at a position higher than the reference surface 11 in the height direction Z. The first semiconductor laser element 21 and the second semiconductor laser element 22 are mounted on the first mounting surface 12a (first mounting portion TR1) and the third semiconductor laser element 23 is mounted on the second mounting surface 12b (second mounting portion TR2). The second mounting surface 12b is provided at a position higher than the first mounting surface 12a and a level difference (mounting surface level difference ML) therebetween is 50 μm.

Note that, the level difference on the base member 10 may be formed by pressing metal or an alloy, which is a material, with a die, may be formed by casting, may be formed by cutting a material in a block shape, or may be formed by etching.

Each of the semiconductor laser elements is constituted by a chip that outputs light and a sub-mount on which the chip is placed. That is, the first semiconductor laser element 21 is constituted by a first chip 21a and a first sub-mount 21b, the second semiconductor laser element 22 is constituted by a second chip 22a and a second sub-mount 22b, and the third semiconductor laser element 23 is constituted by a third chip 23a and a third sub-mount 23b, and each of the sub-mounts is bonded to a corresponding mounting surface. Note that, a surface of the semiconductor laser element, which is in contact with the mounting surface, is hereinafter called, for description, an element bonding surface.

The chip described above has a rectangular parallelepiped shape and outputs light from one of the surfaces facing in a longitudinal direction. A part from which the light is output is located at a position deviated in a thickness direction of the chip and the light is output from a vicinity of any one of the surfaces facing in the thickness direction. Hereinafter, in the chip, the part from which the light is output is called a light emitting point (output point) and a surface close to the light emitting point is called a chip surface. Note that, since the light emitting point is positioned close to the chip surface in the chip, FIG. 1B illustrates that the light emitting point substantially matches the chip surface, but there is no limitation thereto and the light emitting point may be separated from the chip surface.

When the chip is mounted on the sub-mount in the semiconductor laser element, the mounting is performed so that any of the chip surface and a surface facing the chip surface is in contact with a surface of the sub-mount. Specifically, a case where the chip surface is placed on the sub-mount is called junction-down mounting and a case where the surface opposite the chip surface is placed on the sub-mount is called junction-up mounting.

The sub-mount is formed of aluminum nitride, silicon carbide, diamond, or the like and preferably has high thermal conductivity and a thermal expansion coefficient close to that of the chip. The sub-mount and the chip are bonded by solder, metal paste, or the like and the sub-mount and the base member 10 are bonded similarly by solder, metal paste, or the like.

The first semiconductor laser element 21 is configured to output blue light and the first chip 21a is formed of, for example, a GaN-based material. The first sub-mount 21b has a thickness of 200 μm. The first semiconductor laser element 21 is subjected to the junction-up mounting so that a first chip surface 21c is positioned on an upper side in the first chip 21a. As a result, in the first semiconductor laser element 21, a height (first light emission height TL1) from the element bonding surface to the light emitting point is 350 μm.

The second semiconductor laser element 22 is configured to output green light and the second chip 22a is formed of, for example, a GaN-based material. The second sub-mount 22b has a thickness of 200 μm. The second semiconductor laser element 22 is subjected to the junction-up mounting so that a second chip surface 22c is positioned on an upper side in the second chip 22a. As a result, in the second semiconductor laser element 22, a height (second light emission height TL2) from the element bonding surface to the light emitting point is 350 μm similarly to the first semiconductor laser element 21.

The third semiconductor laser element 23 is configured to output red light and the third chip 23a is formed of, for example, a GaAs-based material. The third sub-mount 23b has a thickness of 295 μm. The third semiconductor laser element 23 is subjected to the junction-down mounting so that a third chip surface 23c is positioned on a lower side in the third chip 23a. As a result, in the third semiconductor laser element 23, a height (third light emission height TL3) from the element bonding surface to the light emitting point is 300 μm.

In an optical module including a plurality of semiconductor laser elements, light beams whose positions are made uniform are desired to be output, and when light emitting points are varied in height, an extra optical component for adjustment is required. In the present embodiment, as described above, although the third semiconductor laser element 23 is different from the first semiconductor laser element 21 and the second semiconductor laser element 22 in the height from the element bonding surface to the light emitting point, by mounting the semiconductor laser elements on mounting portions having different heights, heights (reference heights HL) from the reference surface 11 to the light emitting points become equal. That is, a difference between the first light emission height TL1 or the second light emission height TL2 and the third light emission height TL3 is eliminated by the mounting surface level difference ML, and therefore the reference heights HL of the plurality of semiconductor laser elements are substantially made uniform.

As illustrated in FIG. 1A, the plurality of semiconductor laser elements have a longitudinal direction of the chip parallel to the longitudinal direction Y, are arranged on the mounting surface along a boundary between the mounting surface and the reference surface 11, and arrayed in the lateral direction X. That is, an output direction in which light is output from each of the semiconductor laser elements is the longitudinal direction Y and on the reference surface 11 side (a lower side in FIG. 1A). Each of the photodiodes 30 is arranged so as to face a surface (light output surface) of the corresponding chip, from which the light is output.

Meanwhile, in the junction-down mounting, when the light output surface is positioned on an inner side of the sub-mount, the light emitting point is in proximity to the sub-mount, and therefore a beam shape may be disturbed because of being shaded by the sub-mount. Therefore, in the third semiconductor laser element 23 subjected to the junction-down mounting, the light output surface may slightly protrude toward the reference surface 11 side relative to an end of the third sub-mount 23b, with which it is possible to prevent the beam shape from being disturbed.

As described above, in the semiconductor laser element, the height of the light emitting point is affected by the thickness of the sub-mount and a mounting method of the chip. It is advantageous for heat dissipation when the thickness of the sub-mount decreases, and handling is facilitated when the thickness of the sub-mount increases. Here, when a semiconductor laser element for blue light and a semiconductor laser element for green light are compared, although both of them are formed of a GaN-based material, a more amount of heat is generated in the semiconductor laser element for green light when both of them have the same light output. Accordingly, the thickness of the sub-mount is desired to be adjusted in accordance with a wavelength of the semiconductor laser element.

A mounting method of the chip may not be able to be desirably selected depending on the wavelength of the semiconductor laser element in some cases. Specifically, the junction-down mounting may be advantageous for heat dissipation because the light emitting point is near the sub-mount, but when being used for a semiconductor laser element formed of a GaN-based material, characteristics thereof may be deteriorated, and therefore the junction-up mounting has to be used in some cases. For example, it is also concerned that the junction-down mounting may give a negative influence on characteristics, such as causing damage to the light emitting point in bonding to the sub-mount or short circuit of a part to be electrically insulated.

As described above, since the height of the light emitting point of the semiconductor laser element is set in view of various circumstances, it is not always preferable to adjust the height in consideration of only the thickness of the sub-mount. On the other hand, in the invention, it is possible to provide an optical module in which mounting portions having different heights are provided in the base member 10 and heights of the plurality of semiconductor laser elements to the light emitting points are made uniform, and thus an influence on the optical component or the like is eliminated and attachment and adjustment of the optical component or the like are able to be facilitated. That is, the heights of the light emitting points are adjusted by the base member 10, and accordingly the thickness of the sub-mount and the mounting method are able to be set in accordance with a wavelength of each of the semiconductor laser elements.

Moreover, which of the junction-down mounting and the junction-up mounting is suitable varies depending on characteristics of the semiconductor laser element, and by mixing semiconductor laser elements of both the junction-down mounting and the junction-up mounting, an optical module to which semiconductor laser elements of various forms are applicable is able to be provided.

Note that, though the junction-down mounting and the junction-up mounting have been described on the premise that bonding is performed to the sub-mount, the sub-mount is not necessarily required and the chip may be directly bonded to the base member 10 without the sub-mount in between. In this case, heat resistance of the sub-mount is able to be eliminated, and therefore heat dissipation is improved. According to such a configuration, the height of the light emitting point is not able to be adjusted by the sub-mount as in the related art, and therefore the present invention is more effective.

The first semiconductor laser element 21 and the second semiconductor laser element 22 are mounted on the same first mounting surface 12a in the present embodiment, but, without limitation thereto, may be mounted on different mounting surfaces. That is, a structure in which three or more mounting surfaces different from each other in height are provided and all semiconductor laser elements are mounted on different mounting surfaces may be provided.

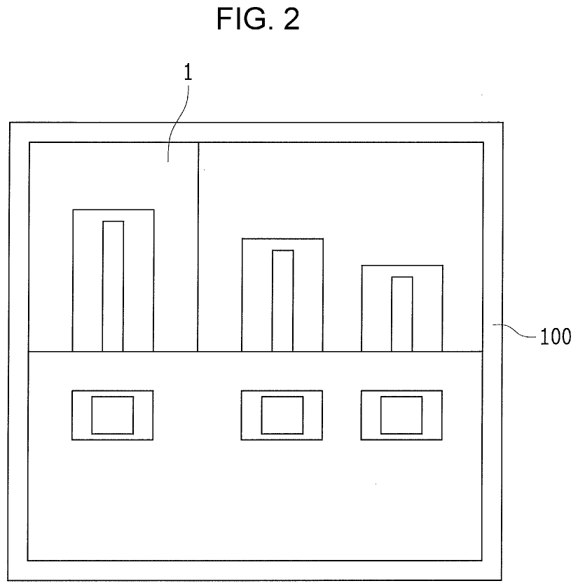

FIG. 2 is a schematic top view illustrating the optical module to which a frame is attached.

To the first module 1, a frame 100 provided so as to surround an outer periphery of the first module 1 is attached. The frame 100 is formed to be higher than the first module 1 and a lid which is not illustrated is attached thereto so as to cover an upper side of the first module 1. When the first module 1 is put inside the frame 100 and the lid, an inside is preferably air-tightly sealed, and thus deterioration caused when the first semiconductor laser element 21 and the second semiconductor laser element 22 are operated is able to be prevented. Note that, a window for light output, a pin for supplying power to the first module 1, or the like may be appropriately provided in the frame 100.

### Second Embodiment

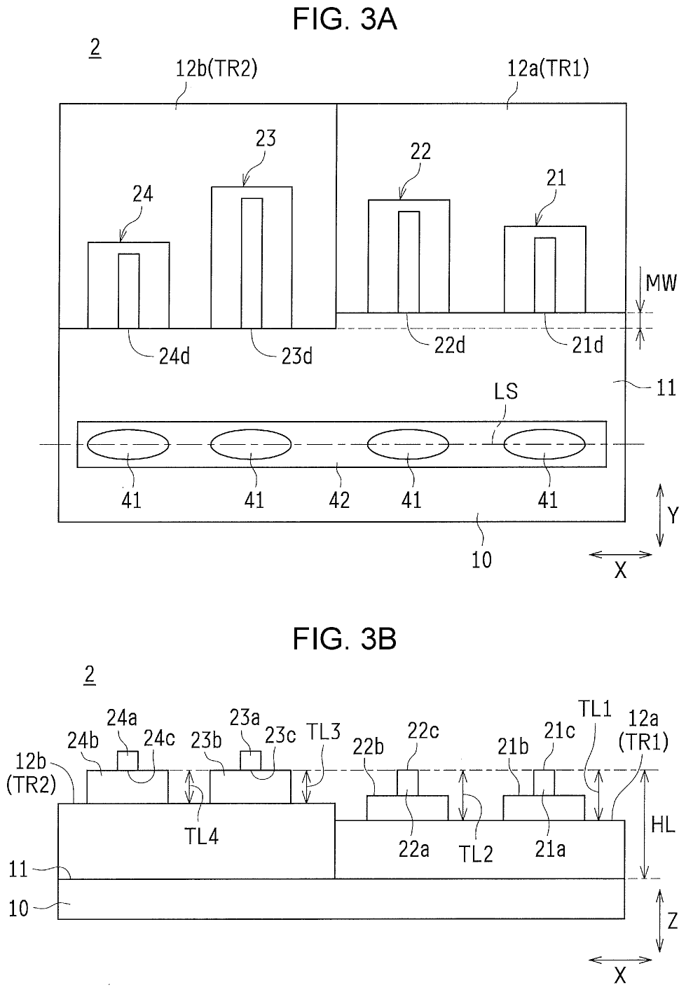

FIG. 3A is a schematic top view of an optical module according to a second embodiment of the invention and FIG. 3B is a schematic side view of the optical module illustrated in FIG. 3A. Note that, a component whose function is substantially equal to that of the first embodiment is given the same reference sign and description thereof will be omitted. Moreover, in FIG. 3B, a collimate lens 41 and the like are omitted so that a positional relationship between semiconductor laser elements is made clear.

The optical module (second module 2) according to the second embodiment of the invention is different from the first module 1 in the number of semiconductor laser elements and regarding a shape of a mounting surface in top view. Specifically, as the semiconductor laser elements, in addition to the first semiconductor laser element 21, the second semiconductor laser element 22, and the third semiconductor laser element 23, a fourth semiconductor laser element 24 is provided.

The fourth semiconductor laser element 24 is substantially similar to the third semiconductor laser element 23 in the configuration, except that the fourth semiconductor laser element 24 outputs infrared light, and is mounted on the second mounting surface 12b. A fourth chip 24a is formed of, for example, a GaAs-based material. A fourth sub-mount 24b has a thickness of 295 μm. The fourth semiconductor laser element 24 is subjected to the junction-down mounting so that a fourth chip surface 24c is positioned on a lower side in the fourth chip 24a. As a result, in the fourth semiconductor laser element 24, a height (fourth light emission height TL4) from the element bonding surface to the light emitting point is 300 μm.

The fourth semiconductor laser element 24 has the fourth light emission height TL4 which is equal to the third light emission height TL3 of the third semiconductor laser element 23 mounted on the second mounting surface 12b and also has the reference height HL which is the same as that of the third semiconductor laser element 23. In this manner, also when the number of semiconductor laser elements is increased, the reference heights HL are able to be made uniform by adjusting the heights by the mounting surface.

The collimate lens 41 is mounted on the reference surface 11 instead of the photodiode 30. Four collimate lenses 41 are provided correspondingly to the semiconductor laser elements and held by a lens holding unit 42 so as to face the corresponding semiconductor laser elements. The four collimate lenses 41 are arranged so that centers thereof match a lens reference line LS parallel to the lateral direction X.

As illustrated in FIG. 3A, in top view, the second mounting surface 12b protrudes toward the reference surface 11 side (a lower side in FIG. 3A) in the longitudinal direction Y relative to the first mounting surface 12a. That is, an end of the second mounting surface 12b is closer to the lens reference line LS by the level difference (surface protruding width MW) between the first mounting surface 12a and the second mounting surface 12b in the longitudinal direction Y. The third semiconductor laser element 23 and the fourth semiconductor laser element 24 are arranged along a boundary between the second mounting surface 12b and the reference surface 11. As a result, a light output surface (third output surface 23d) of the third semiconductor laser element 23 and a light output surface (fourth output surface 24d) of the fourth semiconductor laser element 24 are different from a light output surface (first output surface 21d) of the first semiconductor laser element 21 and a light output surface (second output surface 22d) of the second semiconductor laser element 22 in the position in the longitudinal direction Y. In this manner, since a difference in a focal distance or the like is adjusted by the surface protruding width MW, when the collimate lenses 41 are arranged on the same straight line, for example, installation thereof is facilitated. That is, the same optical component or the like is able to be used for a plurality of light beams whose characteristics are different, for example, where a focal distance is different due to a difference of a wavelength, by shifting a position of a light output surface to reduce the difference of characteristics. Thereby, a reduction in a size of the optical module is able to be achieved, for example, by outputting a plurality of light beams in an overlapping manner with a simple configuration.

Note that, though the present embodiment provides a configuration in which the second mounting surface 12b protrudes toward the reference surface 11 side in the longitudinal direction Y relative to the first mounting surface 12a, there is no limitation thereto and a configuration in which the first mounting surface 12a protrudes may be provided.

### Third Embodiment

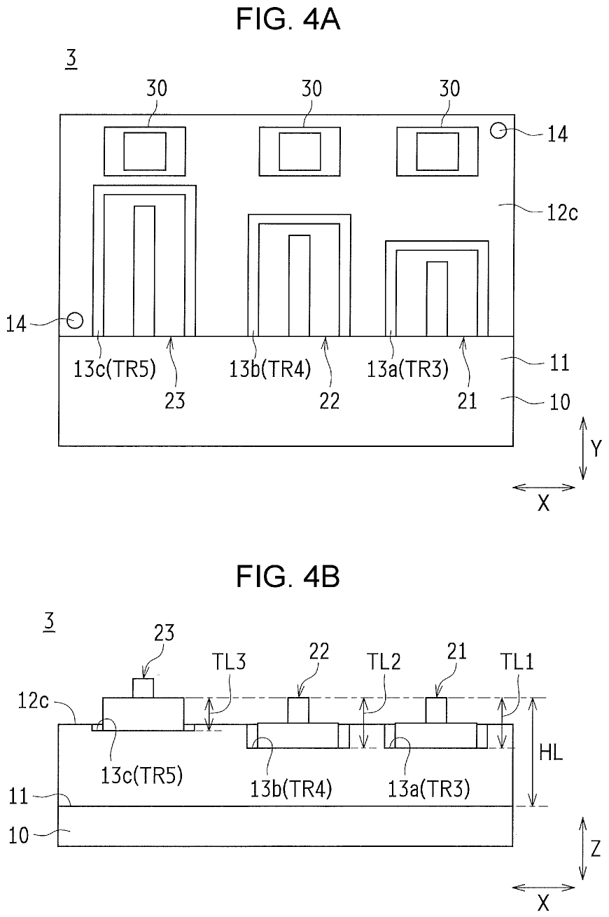

FIG. 4A is a schematic top view of an optical module according to a third embodiment of the invention and FIG. 4B is a schematic side view of the optical module illustrated in FIG. 4A. Note that, a component whose function is substantially equal to those of the first embodiment and the second embodiment is given the same reference sign and description thereof will be omitted.

The optical module (third module 3) according to the third embodiment of the invention is different from the first module 1 in a shape of a mounting surface. In the third module 3, a plurality of recesses are provided on a flat mounting surface (third mounting surface 12c).

Specifically, on the third mounting surface 12c, a first recess 13a (third mounting portion TR3) and a second recess 13b (fourth mounting portion TR4) that have the same depth and a third recess 13c (fifth mounting portion TR5) formed less than the first recess 13a and the second recess 13b are provided. The first semiconductor laser element 21 is mounted in the first recess 13a, the second semiconductor laser element 22 is mounted in the second recess 13b, and the third semiconductor laser element 23 is mounted in the third recess 13c. The plurality of recesses are provided along the reference surface 11 and have one end extended to a boundary between the third mounting surface 12c and the reference surface 11. The plurality of semiconductor laser elements are arranged so that light output surfaces thereof substantially match the boundary between the third mounting surface 12c and the reference surface 11.

In the present embodiment, similarly to the first embodiment, though the third semiconductor laser element 23 is different from the first semiconductor laser element 21 and the second semiconductor laser element 22 in the height from the element bonding surface to the light emitting point, the heights (reference heights HL) from the reference surface 11 to the light emitting points become equal by mounting the semiconductor laser elements in the recesses having different depths. In this manner, by defining a part where the semiconductor laser elements are mounted in a narrow range with a structure that is partially low, the mounting surface is able to be effectively utilized, for example, by placing an optical component in another part. Moreover, since the mounting portions are formed to have a level difference around the mounting portions, it is possible to suppress a case where an adhesive used for bonding the semiconductor laser elements spreads to the surrounding area.

The photodiodes 30 corresponding to the plurality of semiconductor laser elements are mounted on the third mounting surface 12c. Each of the photodiodes 30 is arranged so as to face a surface (back surface) opposite the light output surface. When the mounting surface is flat, an optical component is able to be easily installed and a space is able to be effectively utilized.

Here, the PD chip 31 may be held to be inclined so that a semiconductor laser element side thereof is lower, and when a light receiving surface thereof is inclined, the PD chip 31 easily receives light from the semiconductor laser element. In a case where the photodiode 30 is arranged on a back side (opposite the output direction) of the semiconductor laser element as in the present embodiment, a reflectivity at an end on a back surface of the chip is preferably set to be lower than normal in order to secure a light amount to be received by the photodiode 30. Specifically, the reflectivity at the end on the back surface is, for example, 60 to 90%. Additionally, in a case where the optical module is used with a significantly low output, a reflectivity at an end on the light output surface (front surface) is able to be set to be higher than the reflectivity at the end on the back surface. This makes it possible to accurately adjust intensity of the significantly low output. Further, in a case where the output from the chip is suppressed to be low, it is possible to achieve cost reduction, size reduction, or reduction in power consumption as compared to a case where light after being output is reduced by a filter or the like, and it is possible to avoid an abnormal output due to deterioration of the filter or the like. An example of intended use where the optical module is used with a significantly low output includes a display of a type in which a retina of a human body is scanned with light. Specifically, the reflectivity at the end is, for example, 90% on the front surface and 80% on the back surface.

The third mounting surface 12c is provided with two position reference marks 14. The two position reference marks 14 are positioned to be separated from each other in the lateral direction X and the longitudinal direction Y. For image recognition, for example, in mounting of each member, a position is grasped on the basis of the position reference marks 14, and accuracy of attachment is able to be ensured. The position reference marks 14 are preferably provided at diagonal two or more portions of the third mounting surface 12c in top view. It is sufficient that each of the position reference marks 14 has a reflectivity different from that of the surrounding area in image recognition, and may be formed, for example, by providing irregularities or removing gold-plated part.

In the present embodiment, a recess may be used to grasp a mounting position. Though the semiconductor laser element is arranged in a center of the recess in the lateral direction X in FIG. 4A, the semiconductor laser element may be arranged so as to be in contact with an end of the recess. This makes it possible to accurately control a position of the semiconductor laser element.

Further, the present embodiment provides a configuration in which no level difference is provided in the third mounting surface 12c in the longitudinal direction Y, but there is no limitation thereto and a mounting surface may be provided with a level difference in the longitudinal direction Y as in the second embodiment. As a result, the light output surfaces of the plurality of semiconductor laser elements are configured to be different from each other in the position in the longitudinal direction Y.

### Fourth Embodiment

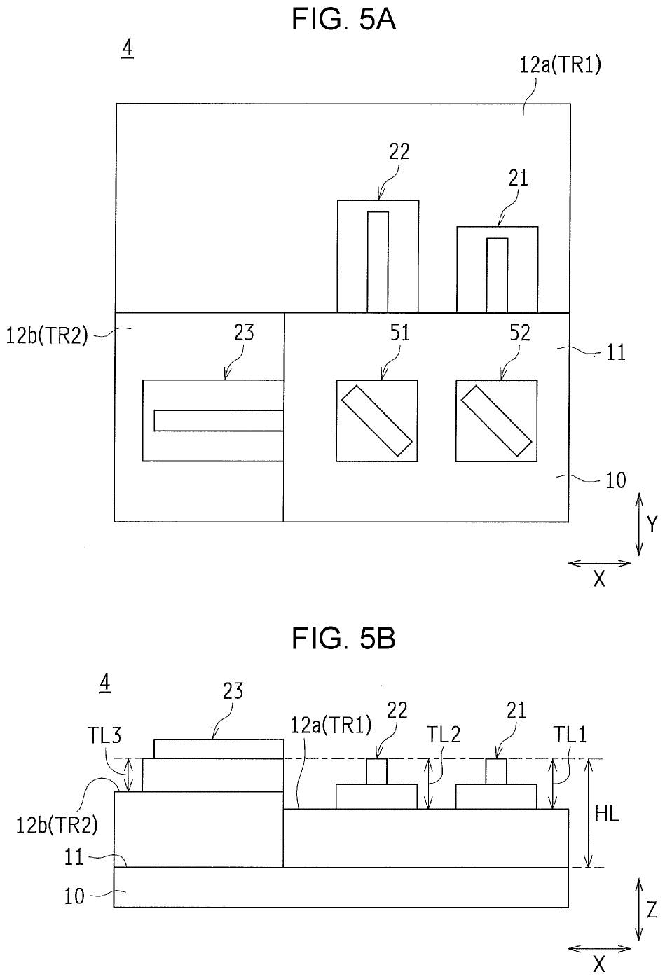

FIG. 5A is a schematic top view of an optical module according to a fourth embodiment of the invention and FIG. 5B is a schematic side view of the optical module illustrated in FIG. 5A. Note that, a component whose function is substantially equal to those of the first embodiment through the third embodiment is given the same reference sign and description thereof will be omitted. Moreover, in FIG. 5B, a wavelength filter and the like are omitted so that a positional relationship between semiconductor laser elements is made clear.

The optical module (fourth module 4) according to the fourth embodiment of the invention is different from the first module 1 in an output direction of a semiconductor laser element. As illustrated in FIG. 5A, the first mounting surface 12a on which the first semiconductor laser element 21 and the second semiconductor laser element 22 are mounted is adjacent to the reference surface 11 in the longitudinal direction Y and the second mounting surface 12b on which the third semiconductor laser element 23 is mounted is adjacent to the reference surface 11 in the lateral direction X. The output direction of the first semiconductor laser element 21 and the second semiconductor laser element 22 is the longitudinal direction Y and on the reference surface 11 side (a lower side in FIG. 5A) and the output direction of the third semiconductor laser element 23 is the lateral direction X (a right side in FIG. 5A). Similarly to the first embodiment, by mounting the plurality of semiconductor laser elements on the corresponding mounting surfaces, the reference heights HL become equal.

On the reference surface 11, a wavelength filter (a first filter 51 and a second filter 52) is mounted through which light is transmitted or by which light is reflected in accordance with a wavelength. The first filter 51 is arranged at a position where light output from the second semiconductor laser element 22 and light output from the third semiconductor laser element 23 cross and the second filter 52 is arranged at a position where light output from the first semiconductor laser element 21 and the light output from the third semiconductor laser element 23 cross.

With the first filter 51, the light output from the second semiconductor laser element 22 is reflected and the light output from the third semiconductor laser element 23 is transmitted.

With the second filter 52, the light output from the first semiconductor laser element 21 is reflected and the light output from the first filter 51 (the light output from the third semiconductor laser element 23 and transmitted by the first filter 51 and the light output from the semiconductor laser element 22 and reflected by the first filter 51) is transmitted. As a result, the second filter 52 outputs light by multiplexing the light output from the first semiconductor laser element 21, the second semiconductor laser element 22, and the third semiconductor laser element 23.

As described above, by mixing the semiconductor laser elements whose output directions are different from each other, the semiconductor laser elements are able to be desirably arranged and flexibility in design of the optical module is able to be improved.

Note that, the reference surface 11 is a surface on which the photodiodes 30 are placed in the embodiments, but may be configured to be a surface on which no photodiode 30 is mounted. That is, a plurality of mounting surfaces that are different in the position in the height direction Z may be set with the surface on which no photodiode 30 is mounted as the reference surface 11. The plurality of mounting surfaces that are different in the position in the height direction Z may be set, for example, by setting a bottom surface of the base member 10 as the reference surface 11 or a top surface of the base member 10 as the reference surface 11. That is, an effect of the invention described above is able to be obtained as long as a configuration is such that a plurality of different semiconductor laser elements have the light emitting points at substantially the same heights in the height direction Z.

Note that, the embodiments disclosed herein are an example in all respects and shall not serve as a basis for limited interpretation. Accordingly, the technical scope of the invention shall not be interpreted only by the aforementioned embodiments, but is defined on the basis of the description of the claims. Moreover, meanings equivalent to the claims and all modification falling in the scope of the claims are included.

Note that, this application claims the benefit of priority to Japanese Patent Application No. 2016-129219 filed on Jun. 29, 2016, the content of which is incorporated herein by reference in its entirety. Furthermore, the entire contents of a reference cited in the present specification are herein specifically incorporated by reference.

### REFERENCE SIGNS LIST

1 first module (example of optical module)
2 second module (example of optical module)
3 third module (example of optical module)
4 fourth module (example of optical module)
10 base member
11 reference surface
12a first mounting surface
12b second mounting surface
12c third mounting surface
13a first recess
13b second recess
13c third recess
21 first semiconductor laser element (example of semiconductor laser element)
21a first chip
21b first sub-mount
21c first chip surface
21d first output surface
22 second semiconductor laser element (example of semiconductor laser element)
22a second chip
22b second sub-mount
22c second chip surface
22d second output surface
23 third semiconductor laser element (example of semiconductor laser element)
23a third chip
23b third sub-mount
23c third chip surface
23d third output surface
24 fourth semiconductor laser element (example of semiconductor laser element)
24a fourth chip
24b fourth sub-mount
24c fourth chip surface
24d fourth output surface
HL reference height
ML mounting surface level difference
MW surface protruding width
TL1 first light emission height
TL2 second light emission height
TL3 third light emission height
TL4 fourth light emission height
X lateral direction
Y longitudinal direction
Z height direction

1. An optical module comprising:
a plurality of semiconductor laser elements that output light of wavelengths different from each other from light emitting points; and
a base member on which the plurality of semiconductor laser elements are mounted, wherein
the plurality of semiconductor laser elements have sub-mounts,
the base member has a reference surface serving as a reference in a height direction and a mounting surface on which the semiconductor laser elements are mounted,
the mounting surface includes a plurality of mounting portions having different positions in the height direction,
at least some of the plurality of semiconductor laser elements having distances different from each other in the height direction from a surface in contact with the mounting surface to the light emitting points, and
the plurality of semiconductor laser elements have distances substantially equal to each other in the height direction from the reference surface to the light emitting points.

2. The optical module according to claim 1, wherein
the plurality of semiconductor laser elements include chips that output light, and
at least one of the plurality of chips is subjected to junction-down mounting and at least one of the other chips is subjected to junction-up mounting.

3. The optical module according to claim 1, wherein
the plurality of semiconductor laser elements include chips that output light, and
the plurality of chips are subjected to junction-down mounting.

4. The optical module according to claim 1, wherein
the plurality of semiconductor laser elements include chips that output light, and
the plurality of chips are subjected to junction-up mounting.

5. The optical module according to claim 1, wherein
in a case where a surface from which light is output is a light output surface and a direction in which light is output is an output direction in the plurality of semiconductor laser elements,
at least two of the plurality of semiconductor laser elements have positions of the light output surface different from each other in the output direction.

6. The optical module according to claim 1, wherein
the mounting surface is provided with a recess formed to be lower than a surrounding area.

7. The optical module according to claim 1, wherein
at least two of the plurality of semiconductor laser elements have directions different from each other in which light is output.
